(19) United States
(12) Patent Application Publication
(10) Pub. No.: US 2007/0287232 A1
(43) Pub. Date: Dec. 13, 2007

(54) BOTTOM GATE THIN FILM TRANSISTOR AND METHOD OF MANUFACTURING THE SAME

(75) Inventors: Hyuck LIM, Yongin-si (KR); Young-soo PARK, Yongin-si (KR); Wenxu XIANYU, Yongin-si (KR); Hans S. CHO, Yongin-si (KR); Huaxiang YIN, Yongin-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/760,043

(22) Filed: Jun. 8, 2007

(30) Foreign Application Priority Data
Jun. 9, 2006 (KR) 10-2006-0052100

(51) Int. Cl. H01L 21/84; H01L 21/00

(52) U.S. Cl. 438/149; 438/491; 257/E29.151

(57) ABSTRACT

A method of manufacturing a bottom gate thin film transistor (“TFT”), in which a polycrystalline channel region having a large grain size is formed relatively simply and easily, includes forming a bottom gate electrode on a substrate, forming a gate insulating layer on the substrate to cover the gate electrode, forming an amorphous semiconductor layer on the gate insulating layer, patterning the amorphous semiconductor layer to form an amorphous channel region on the gate electrode, melting the amorphous channel region using a laser annealing method to form a melted amorphous channel region, and crystallizing the melted amorphous channel region to form a laterally grown polycrystalline channel region.

This application claims priority to Korean Patent Application No. 10-2006-0052100, filed on Jun. 9, 2006, and all the benefits accruing therefrom under 35 U.S.C. §119, the contents of which in its entirety are herein incorporated by reference.

### BACKGROUND OF THE INVENTION

1. Field of the Invention

The present invention relates to a thin film transistor (“TFT”) and a method of manufacturing the same, and more particularly, to a method of manufacturing a bottom gate TFT including a polycrystalline channel region having a large grain size, and a bottom gate TFT manufactured using the method.

2. Description of the Related Art

Active research on a low temperature poly-Si (“LTPS”) TFT, which is used in light sources of organic light emitting display (“OLED”) devices or liquid crystal display (“LCD”) devices, has been conducted recently, and accordingly, research on a system on glass (“SOG”), in which an outer driver integrated circuit (“IC”) is never employed, has been further conducted. The outer driver IC is integrally formed on a display panel, and thus a connection line between the display panel and the outer driver IC is not required. Accordingly, display devices have a reduced error rate and improved reliability. The final purpose of the research is to obtain an LTPS TFT for providing an SOG in which all display systems including data and gate driver ICs, and a controller are integrally formed on the display panel. To achieve this objective, the LTPS should have mobility greater than 400 cm²/Vsec and excellent uniformity. To date, an LTPS having these properties cannot be manufactured using excimer laser annealing (“ELA”), sequential lateral solidification (“SLS”), metal-induced lateral crystallization (“MILC”), or the like which are known to those of ordinary skill in the art.

Polycrystalline silicon is manufactured using various methods. For example, a method of directly depositing polycrystalline silicon and a method of crystallizing amorphous silicon (“a-Si”) after depositing the amorphous silicon can be used. Polycrystalline silicon manufactured by crystallizing has a large grain size. Then the field effect mobility of the polycrystalline silicon is further increased, but the grain size uniformity of the polycrystalline silicon is further reduced. Conventional ELA can only enlarge the grain size of the polycrystalline silicon by a limited amount. To overcome this limit, Kim et al. (Kim et al., IEEE ELECTRON DEVICE LETTERS, VOL 23, P 315-317) suggests a method of manufacturing polycrystalline silicon having a grain size of several micrometers. A lateral grain having a length of 4.6 μm can be manufactured using a method of crystallizing, which requires that an oxide capping layer and an air gap be formed on upper and lower parts of amorphous silicon for controlling crystallization velocity. Accordingly, this method includes an additional operation. In particular, the air gap is formed by forming and removing an additional scarification layer, and the oxide capping layer is removed in a final step. The additional operation is not preferable in view of mass production, and in particular, may affect product yield, thus resulting in increased manufacturing costs.

### BRIEF SUMMARY OF THE INVENTION

The present invention provides a method of manufacturing a bottom gate thin film transistor (“TFT”) in which a polycrystalline channel region having a large grain size can be formed relatively simply and easily.

The present invention also provides a bottom gate TFT manufactured using the method.

According to exemplary embodiments of the present invention, a method of manufacturing a bottom gate TFT includes forming a bottom gate electrode on a substrate, forming a gate insulating layer on the substrate to cover the gate electrode, forming an amorphous semiconductor layer on the gate insulating layer, patterning the amorphous semiconductor layer to form an amorphous channel region on the gate electrode, melting the amorphous channel region using a laser annealing method to form a melted amorphous channel region, and crystallizing the melted amorphous channel region to form a laterally grown polycrystalline channel region.

The amorphous semiconductor layer may be formed of silicon Si or silicon-germanium SiGe, and to have a thickness in a range of about 500 through about 1000 Å. The amorphous channel region may be formed to have a length in a range of about 2 through about 5 μm. A laser energy used in the laser annealing method may be controlled in a range of about 700 through about 1000 mJ/cm². The gate insulating layer may be formed of silicon dioxide SiO₂ or silicon nitride SiN. The electrode layer may be formed of one of aluminum Al, chromium Cr, copper Cu, and molybdenum Mo.

The amorphous semiconductor layer may be patterned using an ultra violet (“UV”) lithography method. The substrate may be a transparent substrate formed of glass or plastic. UV light may be irradiated through the transparent substrate to arrive at the amorphous semiconductor layer with the gate electrode constituting a mask.

According to other exemplary embodiments of the present invention, a bottom gate TFT, including a bottom gate electrode and a laterally grown polycrystalline channel region, is manufactured using the above-described method.

According to the present invention, a bottom gate TFT having improved field effect mobility can be manufactured simply and easily.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1H are cross-sectional views for illustrating an exemplary method of manufacturing an exemplary bottom gate thin film transistor (“TFT”) according to an exemplary embodiment of the present invention; and

FIG. 2 is a scanning electron microscope (“SEM”) photograph of an exemplary polycrystalline silicon channel region obtained by laser annealing as illustrated in FIG. 1E.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thickness of layers and region are exaggerated for clarity. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

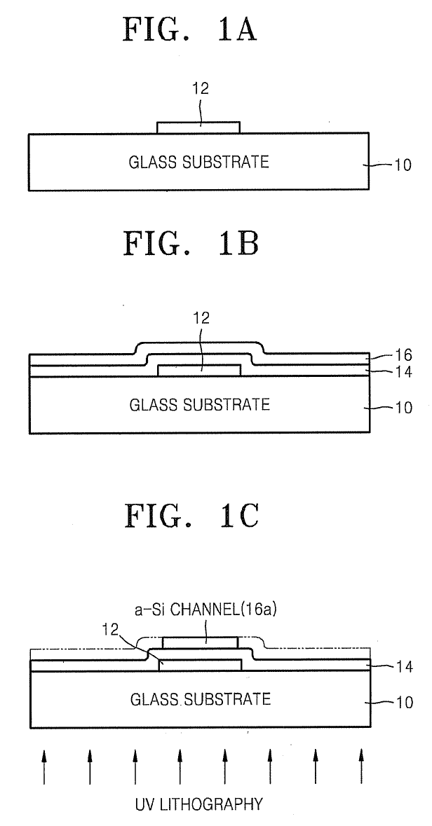

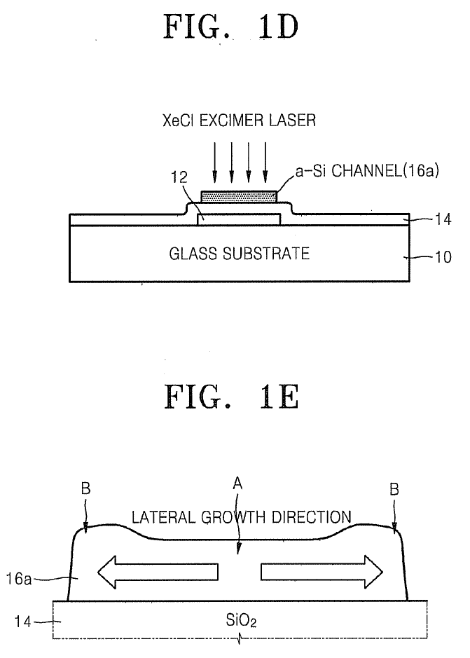

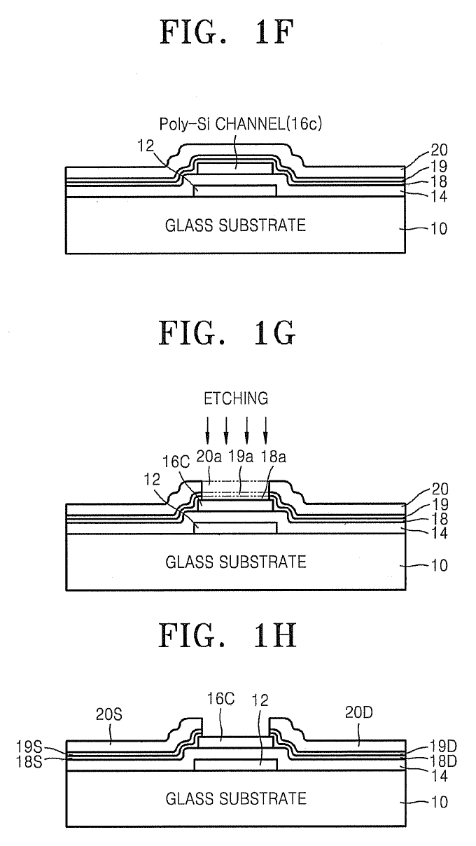

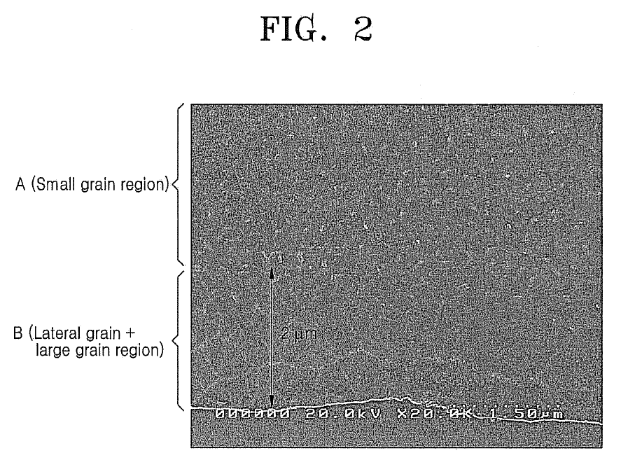

FIGS. 1A through 1H are cross-sectional views for illustrating an exemplary method of manufacturing an exemplary bottom gate thin film transistor (“TFT”) according to an exemplary embodiment of the present invention. Throughout this specification, material layers may be deposited using various methods such as, but not limited to, a chemical vapor deposition (“CVD”) method or a physical vapor deposition (“PVD”) method, which are known to those of ordinary skill in the art, and thus descriptions thereof will be omitted.

Referring to FIGS. 1A and 1B, a gate metal such as aluminum Al, chromium Cr, copper Cu, molybdenum Mo, or the like is deposited on a substrate 10 and patterned to form a bottom gate electrode 12. While only one bottom gate electrode 12 is shown, it should be understood that an array of bottom gate electrodes 12 may be formed on the substrate 10. Also, while particular examples of materials are described for forming the bottom gate electrode 12, other materials may alternatively be used including alloys of materials as well as multi-layer structures. Here, the substrate 10 may be a transparent substrate formed of glass or plastic, but materials of the substrate 10 are not limited thereto.

Next, a gate insulating layer 14 is formed on the substrate 10 so as to cover the bottom gate electrode 12. The gate insulating layer 14 may be formed of an insulation material such as, but not limited to, silicon dioxide SiO₂ or silicon nitride SiN. An amorphous semiconductor layer 16 formed of silicon Si or silicon-germanium SiGe is formed on the gate insulating layer 14. The amorphous semiconductor layer 16 may be formed to have a thickness in the range of about 500 through about 1000 Angstroms Å. The range of the thickness of the amorphous semiconductor layer 16 is advantageous in view of melting and crystallization of the amorphous semiconductor layer 16 in the following laser annealing operation, and for forming a channel region.

Referring to FIG. 1C, the amorphous semiconductor layer 16 is patterned to form an amorphous channel region 16a aligned on and overlapping the bottom gate electrode 12. While the amorphous channel region 16a is illustrated as amorphous silicon (“a-Si”), the amorphous channel region 16a may alternatively be formed of amorphous SiGe. The amorphous semiconductor layer 16 is patterned using an ultra violet (“UV”) lithography method. The substrate 10 may be a glass substrate, or other transparent substrate, having a top surface, on which the bottom gate electrode 12 and gate insulating layer 14 are formed, and a bottom surface opposite the top surface. When UV light is irradiated onto the bottom surface of the substrate 10 on which a laminate is not formed, the UV light may be transmitted into and through the substrate 10 to arrive at the portions of the amorphous semiconductor layer 16 not hidden by the bottom gate electrode 12. When the lithography method is performed using these operations, since the bottom gate electrode 12 is used as a UV mask, an additional operation with a mask is not required for patterning the amorphous semiconductor layer 16. The resultant amorphous channel region 16a thus is formed to have about a same peripheral area as the gate electrode 12, although may be sized slightly different due to undercutting in the lithography process. The amorphous channel region 16a is formed to have a length in the range of about 2 through about 5 μm, for advantageously forming as small a number of grain boundaries as possible within a grain when crystallizing the amorphous channel region 16a. Since grain boundaries have a bad influence on electron mobility within a channel, it is important that the number of grain boundaries in the channel region is minimized.

Referring to FIGS. 1D, 1E, and 1F, the amorphous channel region 16a is melted using a laser annealing method to induce crystallization. An XeCl excimer laser having a wavelength of 308 nm is irradiated to heat and melt the amorphous channel region 16a. The XeCl excimer laser is irradiated in a direction towards a top surface of the amorphous channel region 16a. As illustrated in FIG. 1E, in a melting state, the thickness of a middle part A of the amorphous channel region 16a is different from the thicknesses of opposing ends B of the amorphous channel region 16a. In particular, in the melting state, ends B in a lateral direction are formed to have a thickness greater than the thickness of the middle part A, and the difference between the thickness of the middle part A and the thickness of both ends B has an influence on a cooling velocity. That is, cooling and solidification can be performed in the middle part A faster than in both ends B. Accordingly, a crystalline germ is first generated in the middle part A, and the generated crystalline germ grows from the middle part A to both ends B as time goes by. As result of this crystal growth, a laterally grown polycrystalline channel region 16c, as shown in FIG. 1F, can be formed easily. Also, the position and size of the laterally grown polycrystalline channel region 16c can be determined and controlled easily. The features of FIG. 1E will become more apparent with reference to FIG. 2 which is a scanning electron microscope (“SEM”) photograph of the laterally grown polycrystalline channel region 16c. As shown in FIG. 2, ends of the laterally grown polycrystalline channel region 16c may be about 2 μm.

The laterally grown polycrystalline channel region 16c is formed to have a large grain size, and thus has high mobility and a low defect density. Accordingly, a TFT device can be manufactured to have a small leakage current and an excellent switching property. To improve annealing efficiency, an energy density of the laser may be controlled to be in the range of about 700 through about 1000 mJ/cm².

As further shown in FIG. 1F, after the polycrystalline channel region 16c is formed, a polycrystalline semiconductor layer 18 is formed on the gate insulating layer 14 so as to cover the polycrystalline channel region 16c. An N-type semiconductor layer 19 and an electrode layer 20 are stacked on the polycrystalline semiconductor layer 18 sequentially. Here, the polycrystalline semiconductor layer 18 may be formed of polycrystalline silicon, and the N-type semiconductor layer 19 may be formed of a-Si doped with N-type impurities or polycrystalline silicon doped with N-type impurities. The N-type impurities include atoms such as antimony (Sb), phosphorus (P), arsenic (As), or the like. The electrode layer 20 may be formed of a material, such as that including one of Al, Cr, Cu and Mo. The electrode layer 20 may be formed of the same material as the bottom gate electrode 12. Also, while particular examples of materials are described for forming the electrode layer 20, other materials may alternatively be used including alloys of materials as well as multi-layer structures.

Referring to FIGS. 1G and 1H, an electrode layer part 20a, an N-type semiconductor layer part 19a, and a polycrystalline semiconductor layer part 18a, all of which are formed on the polycrystalline channel region 16c, are etched sequentially to form a source region and a drain region which are formed separated from each other. Here, the source region includes a source electrode 20s, and sources 18s and 19s which are interposed between the source electrode 20s and the polycrystalline channel region 16c to provide an ohmic contact. The drain region includes a drain electrode 20d, and drains 18d and 19d which are interposed between the drain electrode 20d and the polycrystalline channel region 16c to provide an ohmic contact. The sources 18s and 19s may also formed between the source electrode 20s and the gate insulating layer 14, and the drains 18d and 19d may also be formed between the drain electrode 20d and the gate insulating layer 14. Using these operations, a bottom gate TFT device can be manufactured which has improved field effect mobility.

According to exemplary embodiments of the present invention, a polycrystalline channel region having a large grain size can be formed relatively simply and easily without requiring additional operations. In addition, a position of the polycrystalline channel region can be easily determined and controlled. In particular, the laterally grown polycrystalline channel region can be easily formed. Since the laterally grown polycrystalline channel region may have high mobility and a low defect density, a bottom gate TFT having improved field effect mobility can be manufactured using the exemplary method according to the present invention.

The exemplary method of manufacturing a bottom gate TFT according to the present invention can be used in the manufacture of an active matrix LCD (“AMLCD”), an active matrix OLED (“AMOLED”), a solar battery, a semiconductor memory device, or the like, and preferably in the manufacture of a TFT including a glass or plastic substrate and having high mobility and responsiveness. Every electric device including a TFT, an AMLCD, an AMOLED constituting a switching element, an amplifying element, or the like can be manufactured using the method according to the present invention.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a bottom gate thin film transistor, the method comprising:
forming a bottom gate electrode on a substrate;
forming a gate insulating layer on the substrate to cover the gate electrode;
forming an amorphous semiconductor layer on the gate insulating layer;
patterning the amorphous semiconductor layer to form an amorphous channel region on the gate electrode;
melting the amorphous channel region using a laser annealing method to form a melted amorphous channel region; and
crystallizing the melted amorphous channel region to form a laterally grown polycrystalline channel region.

2. The method of claim 1, further comprising:
forming a polycrystalline semiconductor layer on the gate insulating layer covering the polycrystalline channel region;
forming an N-type semiconductor layer on the polycrystalline semiconductor layer;
forming an electrode layer on the N-type semiconductor layer; and
etching sequentially an electrode layer part of the electrode layer, an N-type semiconductor layer part of the N-type semiconductor layer, and a polycrystalline semiconductor layer part of the polycrystalline semiconductor layer, all of which are formed on the polycrystalline channel region, to form a source region and a drain region of each of the electrode layer, N-type semiconductor layer, and polycrystalline semiconductor layer.

3. The method of claim 2, wherein the polycrystalline semiconductor layer is formed of polycrystalline silicon.

4. The method of claim 2, wherein the N-type semiconductor layer is formed of amorphous silicon doped with N-type impurities or polycrystalline silicon doped with N-type impurities.

5. The method of claim 2, wherein the electrode layer is formed of one of aluminum, chromium, copper, and molybdenum.

6. The method of claim 1, wherein the amorphous semiconductor layer is formed of silicon or silicon-germanium.

7. The method of claim 1, wherein the amorphous semiconductor layer is formed to have a thickness in a range of about 500 through about 1000 Å.

8. The method of claim 1, wherein the amorphous channel region is formed to have a length in a range of about 2 through about 5 μm.

9. The method of claim 1, wherein using the laser annealing method includes controlling a laser energy in a range of about 700 through about 1000 mJ/cm².

10. The method of claim 1, wherein the gate insulating layer is formed of silicon dioxide SiO₂ or silicon nitride SiN.

11. The method of claim 1, wherein the gate electrode is formed of one of aluminum, chromium, copper, and molybdenum.

12. The method of claim 1, wherein patterning the amorphous semiconductor layer includes using an ultra violet lithography method.

13. The method of claim 12, wherein the substrate is a transparent substrate formed of glass or plastic.

14. The method of claim 13, wherein using an ultra violet lithography method includes irradiating ultra violet light through the transparent substrate to arrive at the amorphous semiconductor layer with the gate electrode constituting a mask.

15. The method of claim 1, wherein patterning the amorphous semiconductor layer includes using the gate electrode as a mask and forming the amorphous channel region to have about a same peripheral area as the gate electrode.

16. A bottom gate thin film transistor including a bottom gate electrode and a laterally grown polycrystalline channel region, the bottom gate thin film transistor manufactured using a method comprising:
forming the bottom gate electrode on a substrate;
forming a gate insulating layer on the substrate to cover the gate electrode;
forming an amorphous semiconductor layer on the gate insulating layer;
patterning the amorphous semiconductor layer to form an amorphous channel region on the gate electrode;
melting the amorphous channel region using a laser annealing method to form a melted amorphous channel region; and
crystallizing the melted amorphous channel region to form the laterally grown polycrystalline channel region.

17. The bottom gate thin film transistor of claim 16, wherein the amorphous semiconductor layer is formed to have a thickness in a range of about 500 through about 1000 Å.

18. The bottom gate thin film transistor of claim 16, wherein the amorphous channel region is formed to have a length in a range of about 2 through about 5 μm.

19. The bottom gate thin film transistor of claim 16, wherein patterning the amorphous semiconductor layer includes irradiating ultra violet light through the substrate to arrive at the amorphous semiconductor layer with the gate electrode constituting a mask, the polycrystalline channel region having about a same peripheral area as the gate electrode.

20. The bottom gate thin film transistor of claim 16, further comprising a source electrode formed on a first side of the polycrystalline channel region and a drain electrode formed on a second side of the polycrystalline channel region.
